(19) United States
(12) Patent Application Publication
(10) Pub. No.: US 2026/0230081 A1
(43) Pub. Date: Aug. 6, 2026

(54) INTEGRATED CIRCUIT CONFIGURED TO GENERATE A PULSE WIDTH MODULATED SIGNAL

(71) Applicant: STMicroelectronics International N.V., Geneva (CH)

(72) Inventor: Vincent ONDE, Fuveau (FR)

(73) Assignee: STMicroelectronics International N.V., Geneva (CH)

(21) Appl. No.: 19/461,225

(22) Filed: Jan. 27, 2026

(30) Foreign Application Priority Data
Feb. 5, 2025 (FR) FR2501185

(51) Int. Cl. H03M 1/06; G01R 19/00; G01R 19/165; H03M 1/82

(52) U.S. Cl. CPC H03M 1/0614; G01R 19/0092; G01R 19/16552; G01R 19/1659; H03M 1/0607; H03M 1/825

(57) ABSTRACT

An integrated circuit includes a circuit for generating a pulse width modulation signal in current mode. The generation circuit includes a digital-to-analog conversion circuit used to perform slope compensation of a signal generated by a current sensor and having a voltage between a reference voltage and a voltage threshold. The digital-to-analog conversion circuit includes a digital module configured to generate a digital signal, and a conversion module configured to convert the digital signal into a slope compensation analog signal. The digital signal is generated from a clipped digital ramp such that the slope compensation analog signal has a voltage between the reference voltage and the voltage threshold.

### BACKGROUND

### Technical Field

Embodiments and implementations relate to the generation of pulse width modulation signals, in particular for a switching mode power supply.

### Description of the Related Art

A switching mode power supply is an electrical device configured to provide an electrical supply to a load using a switching regulator to convert electrical power.

In particular, the power supply signal is obtained by modulating a direct voltage from a high-frequency signal using a switch, for example a Metal-Oxide-Semiconductor Field-Effect Transistor (also referred to by the abbreviation “MOSFET”) or an Insulated-Gate Bipolar Transistor (also referred to by the abbreviation “IGBT”).

In particular, a pulse width modulation signal (also referred to by the expression as “PWM” signal) is used to control the switch used to transmit the energy provided by the direct voltage to the load. This “PWM” signal thus makes it possible to control the time during which energy is supplied to the load.

A “PWM” signal is characterized by a frequency and by a duty cycle. The frequency defines the number of cycles per second of the “PWM” signal, and thus a period of one cycle of the “PWM” signal. The duty cycle makes it possible to define a time during which the “PWM” signal state is at the high state during a cycle of the “PWM” signal.

The generation of a “PWM” signal can be controlled in voltage mode or in current mode.

The current mode can cause instabilities known as sub-harmonic oscillations when the duty cycle is greater than 50%.

To prevent these instabilities, slope compensation is applied using an additional signal (artificial ramp). Slope compensation makes it possible to eliminate sub-harmonic oscillations and thus stabilize the generation of the “PWM” signal.

In particular, it is possible to generate a digital ramp to perform a slope compensation. In particular, the digital ramp is converted into an analog signal proportional to the digital ramp.

More particularly, a counter may be used to generate this digital ramp by incrementing or decrementing a value of the counter. The counter is configured to carry out a plurality of counting cycles such that the digital signal obtained as output of the counter has a sawtooth shape.

The counter is configured to increment or decrement the value thereof between zero and a maximum value of the counter. Thus, this digital value makes it possible to generate an analog signal having a voltage between 0 Volt and an internal reference voltage Vref, for example a supply voltage Vdd of the integrated circuit.

The analog signal obtained after conversion of the digital ramp is then compared to a signal proportional to a current transmitted to the load. In particular, current sensors may be used to measure the current transmitted to the load and to generate a signal proportional to this current.

However, some current sensors are configured to carry out bidirectional current measurements, for example within the scope of a bidirectional battery charger. For example, such a current sensor may be an anisotropic magnetoresistive sensor or a Hall effect sensor.

These sensors are configured to generate voltages for indicating positive or negative measured currents. These voltages are centered on a non-zero central voltage, for example equal to Vref/2 when the minimum voltage that can be generated is equal to 0 Volt, where Vref is an internal reference voltage, for example the supply voltage Vdd of the integrated circuit or a supply voltage of the current sensor. Voltages below Vref/2 correspond to currents coming from the load and voltages above Vref/2 correspond to currents transmitted to the load.

However, as indicated previously, the analog signal obtained after conversion of the digital ramp varies between 0 Volt and Vref. Thus, the voltage of this analog signal may be inconsistent in relation to the signal generated by the current sensor when it is between 0 Volt and Vref/2 while the voltage generated by the current sensor is between Vref/2 and Vref. It is then not possible to generate a “PWM” signal correctly.

The digital ramp generated for slope compensation is therefore not compatible with such bidirectional current sensors.

Indeed, such a digital ramp is only suitable for unidirectional current sensors referenced to the ground (for example resistive sensors).

### BRIEF SUMMARY

Embodiments of the present disclosure accurately generate a “PWM” signal when a bidirectional current sensor is used to measure a current transmitted to the load.

According to one aspect, an integrated circuit is proposed including a circuit for generating a pulse width modulation signal in current mode, this generation circuit including a digital-to-analog conversion circuit used to perform slope compensation of a signal generated by a current sensor and having a voltage between a reference voltage and a voltage threshold, said digital-to-analog conversion circuit including:

a digital module configured to generate a digital signal, and

a conversion module configured to convert said digital signal into a slope compensation analog signal,

wherein the digital signal is generated from a clipped digital ramp such that the slope compensation analog signal has a voltage between the reference voltage and said voltage threshold.

Such a digital module thus makes it possible to avoid having an inconsistency between the voltage generated by the digital-analog converter and the voltage of a signal generated by the current sensor, by remaining in the same voltage interval.

Such a digital module therefore makes it possible to use a bidirectional current sensor by generating a digital signal respecting the direction of the current transmitted to a load.

Thus, in an advantageous embodiment, said current sensor is a bidirectional current sensor configured to operate over a voltage range limited by a maximum reference voltage and a minimum reference voltage and centered on a non-zero central voltage, for example equal to the maximum reference voltage divided by two when the minimum reference voltage is equal to 0 Volt, the current sensor being configured to generate a signal having a voltage between one of these reference voltages and said non-zero central voltage in a direction of a measured current.

Advantageously, the voltage threshold is between the maximum reference voltage and the non-zero central voltage.

In one embodiment, the digital module includes:

a counter configured to generate a digital ramp,

a clipping module configured to generate the clipped digital ramp by comparing a value of the counter to a first threshold value associated with said voltage threshold.

In an advantageous embodiment, the clipping module is configured to generate the clipped digital ramp by also comparing the value of the counter to a second threshold value associated with said reference voltage.

Advantageously, the counter is configured to increment or decrement the value thereof in order to generate the digital ramp, said value of the counter being incremented or decremented at a frequency defined by a clock signal corresponding to a sub-multiple of a clock used for generating the pulse width modulation signal, the counter defining an increment or decrement step corresponding to a slope of the digital ramp.

In one embodiment, the counter is configured to decrement the value thereof from a maximum value so as to obtain a digital ramp having a negative slope.

In an advantageous embodiment, the first threshold value is a minimum value of the digital signal.

Advantageously, the second threshold value is a maximum value of the digital signal.

In one embodiment, the maximum value of the counter is greater than the maximum value of the digital signal. In this way, such a counter makes it possible to virtually extend the slope compensation beyond the maximum value of the digital signal.

In an advantageous embodiment, the integrated circuit further includes:

a first register configured to store the decrement step of the counter,

a second register configured to store the maximum value of the counter,

a third register configured to store the value of the counter.

Advantageously, the integrated circuit further includes a fourth register configured to store the minimum value of the digital signal.

In one embodiment, the integrated circuit further includes a fifth register configured to store the maximum value of the digital signal

In an advantageous embodiment, the clipping module is configured to:

compare the value of the counter with the first threshold value and with the second threshold value, and

generate as output a value of the digital signal equal to:

the value of the counter when the value of the counter is between the first threshold value and the second threshold value,

the first threshold value when the value of the counter is less than or equal to the first threshold value,

the second threshold value when the value of the counter is greater than or equal to the second threshold value.

Advantageously, the clipping module is configured to compare the value of the counter and to generate the value of the digital signal at each clock stroke of the clock signal corresponding to a sub-multiple of the clock used for generating the pulse width modulation signal.

In one embodiment, the integrated circuit further includes a sixth register configured to store the value of the digital signal generated by the clipping module.

In an advantageous embodiment, the third register is configured to store a number of bits greater than a number of bits that can be stored in the sixth register.

Advantageously, the second register is configured to store a number of bits greater than a number of bits that can be stored in the sixth register. In this way, the second register makes it possible to store a value greater than the dynamics of the digital signal so as to be able to virtually extend the slope compensation beyond the maximum value of the digital signal.

In one embodiment, a method includes generating a pulse width modulation signal with a pulse width modulation circuit in a current mode, receiving, with pulse width modulation circuit, a signal from a current sensor and having a voltage between a reference voltage and a voltage threshold, and performing, with a digital-analog conversion circuit, slope compensation with respect to the signal. The slope compensation includes generating, with a digital module of the analog-digital conversion circuit, a digital signal from a clipped digital ramp and converting, with a conversion module of the digital-analog conversion circuit, the digital signal into a slope compensation analog signal having a voltage between the reference voltage and the voltage threshold based on the clipped digital ramp.

In one embodiment, an integrated circuit includes a pulse width modulation circuit configured to receive a signal from a current sensor and including a digital-analog conversion circuit. The digital-analog conversion circuit includes a digital module configured to generate a digital signal from a clipped digital ramp and a conversion module configured to convert the digital signal into a slope compensation analog signal having a voltage between a reference voltage and a voltage threshold based on the clipped digital ramp.

### BRIEF DESCRIPTION OF THE SEVERAL VIEWS OF THE DRAWINGS

Other advantages and features of the disclosure will become apparent upon examining the detailed description of non-limiting embodiments, and from the appended drawings wherein:

FIG. 1 illustrates an integrated circuit including a circuit for generating a pulse width modulation signal, according to an embodiment;

FIG. 2 illustrates a graph representative of the operation of a magnetoresistive current sensor, according to an embodiment;

FIG. 3 illustrates a digital-to-analog converter used to perform slope compensation in the circuit for generating a pulse width modulation signal;

FIG. 4 illustrates a digital module used in the digital-to-analog converter DAC of FIG. 3, according to an embodiment; and

FIG. 5 illustrates a time diagram showing an evolution over time of the digital value as output of the digital module, according to an embodiment.

### DETAILED DESCRIPTION

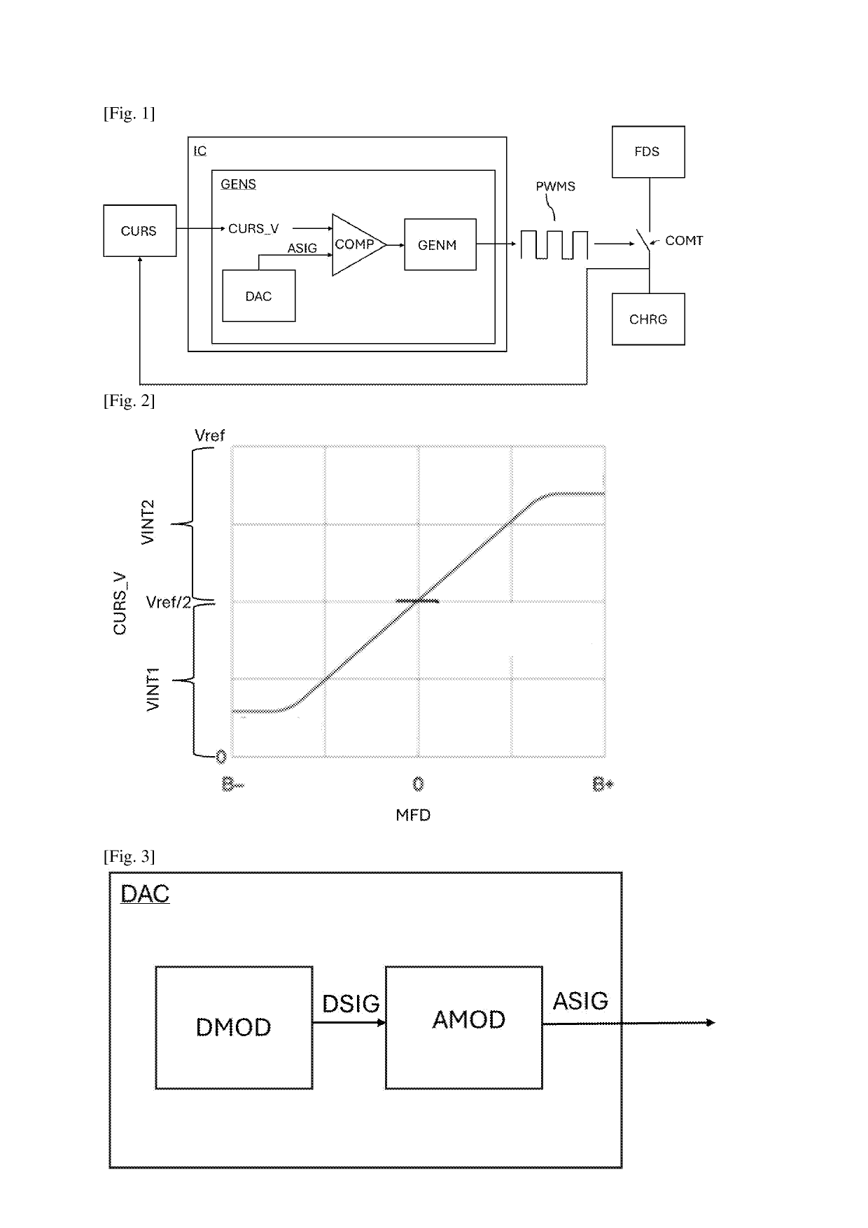

FIG. 1 illustrates an integrated circuit IC including a circuit GENS for generating a pulse width modulation signal, also referred to by the expression “PWM signal”, abbreviation of “Pulse Width Modulation”).

The “PWM” signal generation circuit GENS is configured to generate a “PWM” signal, referenced PWMS, used to control a switch COMT, for example a Metal-Oxide-Semiconductor Field-Effect Transistor (also referred to by the abbreviation “MOSFET”).

The control of the switch COMT can make a switch-mode supply possible for a load CHRG from a direct voltage source FDS. The load CHRG may for example be an electronic system (for example a motherboard of a server) or a battery.

The “PWM” signal has a variable pulse width train, usually at a fixed frequency. A duty cycle of the pulses of the “PWM” signal makes it possible to define the pulse width in relation to a period of the “PWM” signal.

This duty cycle thus makes it possible to define a time of an energy transfer from a direct current power source to the load CHRG. The duty cycle is defined depending on the requirement of the load CHRG in order to maintain the supply voltage of this load CHRG.

These requirements are, for example, deduced from a current measurement in this load CHRG. The generation of the “PWM” signal is then carried out in a common mode.

In particular, a current sensor CURS can be used to measure the current in the load. The current sensor CURS is in particular a current sensor CURS able to carry out bidirectional measurements of the current in the load. For example, the current sensor CURS is an anisotropic magnetoresistive sensor or a Hall effect sensor.

The current sensor CURS is configured to generate a voltage CURS_V depending on the measured current. The voltage has a signed value centered on a central voltage, in particular equal to Vref/2 when the minimum voltage that can be generated by the current sensor is equal to 0 Volt, where Vref is an internal reference voltage, for example the supply voltage Vdd of the integrated circuit or a supply voltage of the current sensor CURS.

For example, FIG. 2 illustrates a graph representative of the operation of a magnetoresistive current sensor. The voltage CURS_V generated by the current sensor depends on a magnetic flux density MFD proportional to the monitored current. The voltage generated by the current sensor can be within two voltage intervals VINT1 and VINT2. A first voltage interval VINT1 is defined between 0 Volt and the central voltage, for example equal to the reference voltage divided by two Vref/2. A second voltage interval VINT2 is defined between the central voltage, for example equal to Vref/2, and the reference voltage Vref. The voltage generated by the current sensor depends on the signal of the monitored current. Thus, for example, when a current is supplied to the load CHRG, the voltage generated by the current sensor is in the second interval VINT2.

Returning to FIG. 1, the “PWM” signal generation circuit GENS is configured to receive the voltage CURS_V generated by the current sensor.

The “PWM” signal generation circuit GENS includes a comparator COMP. This comparator COMP has a first input configured to receive a voltage CURS_V generated by the current sensor, and a second input configured to receive an analog signal ASIG defining a threshold voltage corresponding to a desired voltage setpoint. The desired voltage is defined depending on a desired average current to supply the load CHRG.

The analog signal ASIG is generated by a digital-to-analog converter circuit DAC of the “PWM” signal generation circuit GENS.

The “PWM” signal generation circuit GENS further includes a “PWM” signal generation module GENM. This “PWM” signal generation module GENM is configured to generate the “PWM” signal from the output of the comparator COMP.

In particular, the “PWM” signal generation module GENM is configured to generate pulses at the frequency of a clock. The output of the comparator COMP makes it possible to trigger a reset of a current ramp generated by the “PWM” signal generation module GENM, and therefore the end of a pulse at each cycle.

In order to avoid instabilities known as sub-harmonic oscillations when the duty cycle of the “PWM” signal is greater than 50%, the digital-to-analog converter circuit DAC is configured to generate an analog signal ASIG defining a threshold voltage that may vary over time in order to perform a slope compensation relative to the current ramp of the signal generated by the current sensor.

In particular, the level of the threshold voltage may follow a voltage ramp for stabilizing the operation of the “PWM” signal generation circuit. This slope makes it possible to eliminate the sub-harmonic oscillations when the duty cycle of the “PWM” signal is greater than 50%.

FIG. 3 illustrates one embodiment of a digital-to-analog converter DAC used to perform slope compensation in the circuit GENS for generating a “PWM” signal. The digital-to-analog converter DAC includes a digital module DMOD and a conversion module AMOD. The digital module DMOD is a programmable digital circuit configured to generate a digital signal DSIG of which the value varies over time. This digital signal DSIG is used to perform slope compensation after being converted into an analog signal ASIG by the conversion module AMOD.

In particular, the conversion module AMOD is configured to generate an analog signal ASIG having a voltage conditioned by the digital value VAL carried by the digital signal DSIG. More particularly, the conversion module AMOD includes in particular a plurality of current sources, or a plurality of voltage sources, individually controlled by the bits of the digital signal DSIG in order to generate the analog signal ASIG as output of the conversion module AMOD.

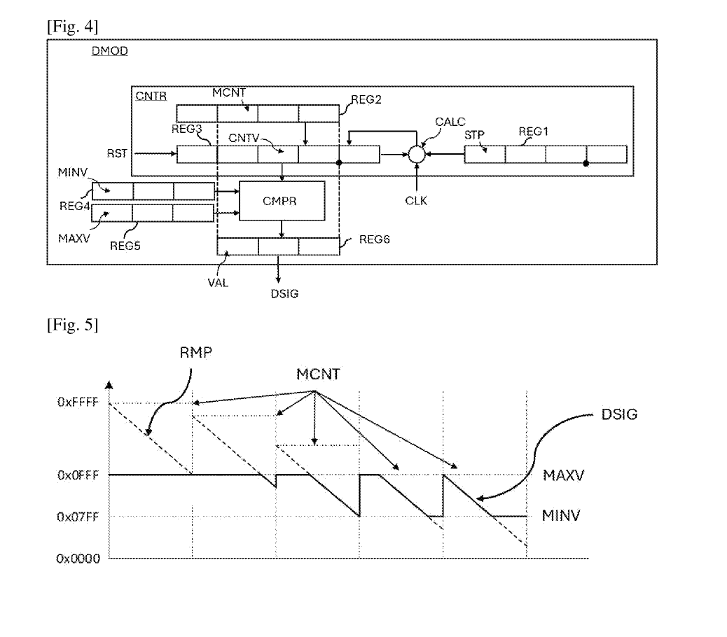

FIG. 4 illustrates one embodiment of a digital module DMOD used in the digital-to-analog converter DAC of FIG. 3.

As seen previously, the digital module DMOD is configured to generate a digital value VAL varying over time to form the digital signal DSIG.

In particular, the digital module DMOD includes a counter CNTR used to define the digital value VAL as output of the digital module DMOD.

More particularly, the counter includes a register REG1 for storing a step value STP of the counter. The step STP of the counter is defined according to the slope of the supply current.

The counter CNTR also includes a register REG2 for storing a maximum value MCNT of the counter. This maximum value MCNT of the counter CNTR is defined such that the midpoint value of the counter CNTR can be associated with an average supply current of the desired load CHRG. This maximum value MCNT can be changed over time.

The counter CNTR includes a register REG3 for storing the digital value CNTV of the counter CNTR. The digital value CNTV of the counter can be initialized to the maximum value MCNT when the counter is configured to decrement the value CNTV thereof stored in the register REG3. Otherwise, the digital value CNTV can be initialized to zero if the counter is configured to increment the value CNTV thereof stored in the register REG3. The digital value CNTV can be reset from a reset RST signal. The signal RST is provided by the “PWM” signal generation module GENM.

The counter CNTR also includes a module CALC for incrementing or decrementing the value of the counter operating according to a clock signal CLK. This clock signal CLK corresponds to a sub-multiple of the clock used by the “PWM” signal generation module GENM to generate the PWMS signal. The frequency of the clock signal CLK may be one or two orders of magnitude lower than the frequency of the clock used to generate the PWMS signal. For example, the clock used to generate the PWMS signal may have a frequency of 250 MHz and the clock signal CLK may have a frequency of 15 MHz.

At each clock stroke of the signal CLK, the contents of the registers REG1 and REG3 are read and the digital value CNTV is incremented or decremented by the value STP stored in the register REG1.

In particular, this CALC module can be configured to decrement the value stored in the register REG3 from the maximum value of the counter to zero with the step defined in the register REG1 according to the clock signal CLK. In this case, the incrementation is carried out by a subtractor circuit.

Alternatively, the module CALC may be configured to increment the value stored in the register REG3 from zero to the maximum value of the counter with the step defined in the register REG1 according to the clock signal CLK. In this case, the incrementation is carried out by an adding circuit.

The counter CNTR is thus able to generate a digital ramp, in particular between zero and a maximum value MCNT. The slope of the digital ramp is positive when the counter is configured to increment the value CNTV thereof. The digital ramp slope is negative when the counter is configured to decrement the value CNTV thereof.

The digital module DMOD further includes a register REG4 for storing a minimum value MINV. This minimum value MINV corresponds to a minimum digital value that can be generated as output of the digital module DMOD.

The digital module also includes a register REG5 for storing a maximum value MAXV. This maximum value MAXV corresponds to a maximum digital value that can be generated as output of the digital module DMOD. This maximum numerical value MAXV can correspond to the value for obtaining a maximum value of the desired supply current.

The digital module DMOD also includes a clipping module CMPR. The clipping module CMPR is configured to compare the value of the counter with the minimum value and with the maximum value and to generate a digital value as output depending on a result of this comparison.

In particular, when the value CNTV of the counter CNTR is greater than the minimum value MINV and less than the maximum value MAXV, the digital value generated as output of the clipping module CMPR corresponds to the value CNTV of the counter CNTR.

When the value CNTV of the counter CNTR stored in the register REG3 is less than or equal to the minimum value MINV, the numerical value VAL generated as output of the clipping module corresponds to the minimum value MINV stored in the register REG4.

When the value CNTV of the counter CNTR stored in the register REG3 is greater than or equal to the maximum value MAXV, the numerical value VAL generated as output of the clipping module corresponds to the maximum value MAXV stored in the register REG5.

The digital module DMOD also includes an output register REG6. This output register REG6 is configured to store the digital value VAL as output of the clipping module CMPR.

This output register REG6 is connected to the conversion module AMOD described in relation to FIG. 3 in order to be able to transmit this digital value VAL to the conversion module AMOD. The conversion module AMOD is then configured to convert this digital value into a voltage associated with this digital value.

Advantageously, the minimum value MINV of the digital module DMOD is chosen to correspond to a fixed voltage level greater than 0 V. For example, the minimum value MINV of the digital module DMOD is chosen to correspond to a voltage level greater than or equal to Vref/2.

Such a minimum value MINV makes it possible for example to limit the digital value as output of the digital module DMOD to a midpoint value of the digital module DMOD.

Such a minimum value MINV therefore makes it possible to prevent the voltage as output of the conversion module AMOD from being lower than the voltage Vref/2.

Such a digital module DMOD makes it possible to support a current sensor CURS adapted to carry out a bidirectional current measurement, in particular an anisotropic magnetoresistive sensor or a Hall effect sensor, not referenced to the ground. Such a digital module DMOD is also adapted to support a unidirectional current sensor referenced to the ground. Indeed, it is possible to define a maximum value MAXV of the digital signal corresponding to the reference voltage Vref and a minimum value MINV of the digital signal corresponding to a zero voltage, as well as a maximum value MCNT of the counter CNTR corresponding to the maximum value MAXV of the digital signal.

Advantageously, the value MAXV of the counter is adapted in relation to the value MINV defined.

Furthermore, the maximum value of the counter CNTR may be greater than the maximum value MAXV as output of the digital module. Thus, the maximum value of the counter CNTR extends beyond the dynamics of the output of the digital module DMOD. This makes it possible to use the entire dynamics of the output of the digital module DMOD. Thus, such a counter makes it possible to virtually extend the slope compensation beyond the maximum value MAXV as output of the digital module.

In one embodiment, the storage register REG3 is configured to store a higher number of bits than can be stored in the storage register REG2, and the storage register REG2 is configured to store a higher number of bits than can be stored in the registers REG4, REG5, and REG6.

For example, the storage register REG1 is over 16 bits, of which 4 bits for a fractional portion of the value stored by this register. The fractional portion makes it possible to improve the accuracy of the slope of the ramp generated by the electronic module. The register REG2 is over 16 bits to store an integer.

The register REG3 is over 20 bits, of which 4 bits for a fractional portion of the stored value. The fractional portion makes it possible to increase the precision of the definition of the slope of the digital ramp. Thus, instead of having a minimum increment of 1, it is possible to have a minimum increment up to 1/16. In this case, 16 cycles of the clock signal CLK are called for for the value to decrease by one unit on the signal DSIG supplied to the conversion module AMOD.

The registers REG4 and REG5 are over 12 bits to store integers. The register REG6 is over 12 bits to store integers.

The bits of the register REG2 are used as bits of the integer portion of the value of the counter stored in register REG3 when the register REG3 is initialized. The 16 high-weight bits of the integer of the stored value of the counter of the register REG3 are used to update the output register REG6 when this value is between the minimum value MINV and the maximum value MAXV. This makes it possible to avoid adapting the output of the digital module DMOD to the interface of the conversion module AMOD that works as a whole value.

For example, the maximum value of the counter can be defined in hexadecimal up to the value 0xFFFF, the maximum value MAXV of the digital module can be defined at 0x0FFF, and the minimum value MINV can be defined at 0x07FF.

In FIG. 4, the illustrations of the registers REG1 to REG6 show vertical bars delimiting aggregates of 4 bits, i.e., a nibble.

FIG. 5 illustrates an example of a time diagram showing an evolution over time of the digital value as output of the digital module DMOD.

In particular, the signal DSIG corresponds to the digital value as output of the digital module over time.

The signal RMP corresponds to the value CNTV of the counter over time. The counter CNTV is here configured to decrement the value CNTV thereof.

In this implementation, the maximum value MAXV of the digital module can be defined at 0x0FFF, and the minimum value MINV can be defined at 0x07FF.

Thus, as seen previously, the digital value as output of the digital module is equal to the maximum value MAXV when the value of the counter is greater than or equal to the maximum value MAXV, and is equal to the minimum value MINV when the value of the counter is less than or equal to the minimum value MINV. Furthermore, the digital value as output of the digital module is equal to the value of the counter when the value CNTV of the counter is between the minimum value MINV and the maximum value MAXV.

The initial value MCNT for each cycle of the counter CNTR is defined according to a desired average current to supply the load CHRG.

In one embodiment, an integrated circuit includes a circuit (GENC) for generating a pulse width modulation signal in current mode, this generation circuit (GENC) including a digital-analog conversion circuit (DAC) used to perform slope compensation with respect to a signal (CURS_V) generated by a current sensor (CURS) and having a voltage between a reference voltage and a voltage threshold, said digital-analog conversion circuit (DAC) including: a digital module (DMOD) configured to generate a digital signal, and a conversion module (AMOD) configured to convert said digital signal into a slope compensation analog signal, wherein the digital signal is generated from a clipped digital ramp such that the slope compensation analog signal has a voltage between the reference voltage and said voltage threshold.

In one embodiment, the current sensor (CURS) is a bidirectional current sensor configured to operate over a voltage range limited by a maximum reference voltage and a minimum reference voltage and centered on a non-zero voltage, the current sensor being configured to generate a signal (CURS_V) having a voltage between one of these reference voltages and said non-zero central voltage in a direction of a measured current.

In one embodiment, the voltage threshold is between the maximum reference voltage (Vref) and the non-zero voltage.

In one embodiment, the digital module (DMOD) includes: a counter (CNTR) configured to generate a digital ramp, a clipping module (CMPR) configured to generate the clipped digital ramp by comparing a value of the counter with a first threshold value associated with said voltage threshold.

In one embodiment, the clipping module (CMPR) is configured to generate the clipped digital ramp by also comparing the value of the counter with a second threshold value associated with said reference voltage.

In one embodiment, the counter (CNTR) is configured to increment or decrement the value thereof in order to generate the digital ramp, said value of the counter being incremented or decremented at a frequency defined by a clock signal (CLK) corresponding to a sub-multiple of a clock used for generating the pulse width modulation signal, the counter (CNTR) defining an increment or decrement step corresponding to a slope of the digital ramp.

In one embodiment, the counter (CNTR) is configured to decrement the value thereof from a maximum value so as to obtain a digital ramp having a negative slope.

In one embodiment, the first threshold value is a minimum value of the digital signal.

In one embodiment, the second threshold value is a maximum value of the digital signal.

In one embodiment, the maximum value of the counter is greater than the maximum value of the digital signal.

In one embodiment, the integrated circuit further includes: a first register (REG1) configured to store the decrementation step of the counter (CNTR), a second register (REG2) configured to store the maximum value of the counter, a third register (REG3) configured to store the value of the counter (CNTR).

In one embodiment, the integrated circuit according further includes a fourth register (REG4) configured to store the minimum value of the digital signal.

In one embodiment, the circuit further includes a fifth register (REG5) configured to store the maximum value of the digital signal.

In one embodiment, the clipping module is configured to: compare the value of the counter with the first threshold value and with the second threshold value, and generate as output a value of the digital signal equal to: the value (CNTV) of the counter when the value (CNTV) of the counter is between the first threshold value and the second threshold value, the first threshold value when the value (CNTV) of the counter is less than or equal to the first threshold value, the second threshold value when the value (CNTV) of the counter is greater than or equal to the second threshold value.

In one embodiment, the clipping module (CMPR) is configured to compare the value of the counter and to generate the value of the digital signal at each clock stroke of the clock signal (CLK) corresponding to a sub-multiple of the clock used for generating the pulse width modulation signal.

In one embodiment, the integrated circuit further includes a sixth register configured to store the value of the digital signal generated by the clipping module.

In one embodiment, the third register (REG3) is configured to store a number of bits greater than a number of bits that can be stored in the sixth register (REG6).

In one embodiment, the second register (REG2) is configured to store a number of bits greater than a number of bits that can be stored in the sixth register (REG6).

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An integrated circuit comprising:
a circuit configure to generate a pulse width modulation signal in a current mode and including a digital-analog conversion circuit configured to perform slope compensation with respect to a signal received by the circuit from a current sensor and having a voltage between a reference voltage and a voltage threshold, the digital-analog conversion circuit including:
a digital module configured to generate a digital signal; and
a conversion module configured to convert the digital signal into a slope compensation analog signal, wherein the digital signal is generated from a clipped digital ramp such that the slope compensation analog signal has a voltage between the reference voltage and the voltage threshold.

2. The integrated circuit according to claim 1, wherein the current sensor is a bidirectional current sensor configured to operate over a voltage range limited by a maximum reference voltage and a minimum reference voltage and centered on a non-zero voltage, the current sensor being configured to generate a signal having a voltage between one of these reference voltages and the non-zero central voltage in a direction of a measured current.

3. The integrated circuit according to claim 2, wherein the voltage threshold is between the maximum reference voltage and the non-zero voltage.

4. The integrated circuit according to claim 1, wherein the digital module includes:
a counter configured to generate a digital ramp,
a clipping module configured to generate the clipped digital ramp by comparing a value of the counter with a first threshold value associated with the voltage threshold.

5. The integrated circuit according to claim 4, wherein the clipping module is configured to generate the clipped digital ramp by also comparing the value of the counter with a second threshold value associated with the reference voltage.

6. The integrated circuit according to claim 4, wherein the counter is configured to increment or decrement the value thereof in order to generate the digital ramp, the value of the counter being incremented or decremented at a frequency defined by a clock signal corresponding to a sub-multiple of a clock used for generating the pulse width modulation signal, the counter defining an increment or decrement step corresponding to a slope of the digital ramp.

7. The integrated circuit according to claim 6, wherein the counter is configured to decrement the value thereof from a maximum value so as to obtain a digital ramp having a negative slope.

8. The integrated circuit according to claim 7, wherein the first threshold value is a minimum value of the digital signal, wherein the second threshold value is a maximum value of the digital signal, wherein the maximum value of the counter is greater than the maximum value of the digital signal.

9. The integrated circuit according to claim 8, wherein the second threshold value is a maximum value of the digital signal.

10. The integrated circuit according to claim 9, wherein the maximum value of the counter is greater than the maximum value of the digital signal.

11. The integrated circuit according to claim 7, further comprising:
a first register configured to store the decrementation step of the counter,
a second register configured to store the maximum value of the counter,
a third register configured to store the value of the counter.

12. The integrated circuit according to claim 8, further comprising a fourth register configured to store the minimum value of the digital signal.

13. The integrated circuit according to claim 9, further comprising a fifth register configured to store the maximum value of the digital signal.

14. The integrated circuit according to claim 7 further comprising a sixth register configured to store the value of the digital signal generated by the clipping module, wherein the clipping module is configured to:
compare the value of the counter with the first threshold value and with the second threshold value, and
generate as output a value of the digital signal equal to:
the value of the counter when the value of the counter is between the first threshold value and the second threshold value,
the first threshold value when the value of the counter is less than or equal to the first threshold value,
the second threshold value when the value of the counter is greater than or equal to the second threshold value;
the clipping module is configured to compare the value of the counter and to generate the value of the digital signal at each clock stroke of the clock signal corresponding to a sub-multiple of the clock used for generating the pulse width modulation signal, wherein the third register is configured to store a number of bits greater than a number of bits that can be stored in the sixth register, wherein the second register is configured to store a number of bits greater than a number of bits that can be stored in the sixth register.

15. A method, comprising:
generating a pulse width modulation signal with a pulse width modulation circuit in a current mode;
receiving, with pulse width modulation circuit, a signal from a current sensor and having a voltage between a reference voltage and a voltage threshold;
performing, with a digital-analog conversion circuit, slope compensation with respect to the signal, including:
generating, with a digital module of the analog-digital conversion circuit, a digital signal from a clipped digital ramp; and
converting, with a conversion module of the digital-analog conversion circuit, the digital signal into a slope compensation analog signal having a voltage between the reference voltage and the voltage threshold based on the clipped digital ramp.

16. The method of claim 15, wherein the current sensor is a bidirectional current sensor configured to operate over a voltage range limited by a maximum reference voltage and a minimum reference voltage and centered on a non-zero voltage, the current sensor being configured to generate the signal having a voltage between one of these reference voltages and the non-zero central voltage in a direction of a measured current.

17. The method of claim 16, wherein the voltage threshold is between the maximum reference voltage and the non-zero voltage.

18. An integrated circuit comprising:
a pulse width modulation circuit configured to receive a signal from a current sensor and including:
a digital-analog conversion circuit including:
a digital module configured to generate a a digital signal from a clipped digital ramp; and
a conversion module configured to convert the digital signal into a slope compensation analog signal having a voltage between a reference voltage and a voltage threshold based on the clipped digital ramp.

19. The integrated circuit of claim 18, wherein the digital module includes a counter configured to generate a digital ramp.

20. The integrated circuit of claim 19, wherein the digital module includes a clipping module configured to generate the clipped digital ramp by comparing a value of the counter with a first threshold value associated with the voltage threshold.
